(19) United States
(12) Patent Application Publication
(10) Pub. No.: US 2006/0000641 A1
(43) Pub. Date: Jan. 5, 2006

(54) Laser metallization for ceramic device

(76) Inventors: Islam A. Salama, Chandler, AZ (US); Cengiz A. Palanduz, Chandler, AZ (US)

Correspondence Address: SCHWEGMAN, LUNDBERG, WOESSNER & KLUTH, 1600 TCF TOWER, 121 SOUTH EIGHT STREET, MINNEAPOLIS, MN, 55402, US

(21) Appl. No.: 10/881,686

(22) Filed: Jun. 30, 2004

(51) Int. Cl. H05K 1/11

(52) U.S. Cl. 174/264; 29/852

(57) ABSTRACT

An apparatus includes a substrate of ceramic material, and a conductive path associated with the substrate formed by a laser directed at the ceramic material.

### FIELD OF THE INVENTION

The present invention is related to formation of structures associated with semiconductor devices. More specifically, the present invention relates to methods and apparatus for forming a ceramic device.

### BACKGROUND OF THE INVENTION

Integrated circuits have been manufactured for many years. Manufacturing integrated circuits involves integrating various active and passive circuit elements into a piece of semiconductor material, referred to as a die. The die is encapsulated into a ceramic or plastic package. In some applications, these packages are directly attached to a printed circuit board by connecting pins, which are arranged along the periphery of the package. An electronic system can be formed by connecting various integrated circuit packages to a printed circuit board.

As advances in semiconductor manufacturing technology led to substantially increased numbers of transistors on each integrated circuit, it became possible to correspondingly increase the functionality of each integrated circuit. In turn, increased functionality resulted in the need to increase the number of input/output (I/O) connections between the integrated circuit and the rest of the electronic system of which the integrated circuit was a part. One adaptation designed to address the increased need for I/O connections was to simply add additional pins to the package. Unfortunately, adding pins to the package increased the area consumed by the package.

A further adaptation designed to address the increased need for I/O connections without consuming an unacceptably large amount of area was the development of ball grid array (BGA) packages. BGA packages include a plurality of solder bumps formed by a process commonly referred to as controlled collapsed chip connection (C4). In such a package, a large number of I/O connection terminals are disposed in a two dimensional array over a substantial portion of a major surface of the package. In some instances, BGA packages are directly attached to a supporting substrate such as a printed circuit board. In other instances, an interposer is directly attached to the printed circuit board, and the BGA package is attached to the interposer. The interposer includes routing traces and vias that connect the solder bumps of the BGA to contacts that are attached to the printed circuit board. The interposer “fans-out” the relatively small die pad pitch of the integrated circuit to the larger contact pad pitch of the printed circuit board. In many applications, the interposer material has a coefficient of thermal expansion value between the value of the coefficient of thermal expansion of the printed circuit board and the value of the coefficient of thermal expansion of the BGA package. The interposer, therefore, reduces mechanical stress induced by different coefficients in thermal expansion between the package and the printed circuit board.

### BRIEF DESCRIPTION OF THE DRAWINGS

The invention is pointed out with particularity in the appended claims. However, a more complete understanding of the present invention may be derived by referring to the detailed description of some of the embodiments when considered in connection with the figures, wherein like reference numbers refer to similar items throughout the figures, and:

FIG. 1 is a top view of a printed circuit board having a package with an interposer attached to the printed circuit board, according to an embodiment of the invention.

FIG. 2 illustrates a schematic cross-sectional view of a package having a die, an interposer and a substrate, according to an embodiment of this invention.

FIG. 3 illustrates a schematic cross-sectional view of an interposer or electrical device, according to an embodiment of this invention.

FIG. 4 illustrates a schematic exploded side view of an interposer or electrical device having a plurality of layers, according to an embodiment of this invention.

FIG. 5 illustrates a schematic side view of an interposer or electrical device with multiple laminated layers, according to an embodiment of this invention.

FIG. 6 illustrates a schematic side view of an interposer or electrical device with multiple laminated layers having an opening formed in the interposer, according to an embodiment of this invention.

FIG. 7 illustrates a schematic side view of an interposer or electrical device with multiple laminated layers having an opening therein, according to an embodiment of this invention.

FIG. 8 illustrates a schematic side view of an opening in the interposer or electrical device undergoing laser treatment, according to an embodiment of this invention.

FIG. 9 illustrates a schematic cross-sectional view of an opening in the interposer or electrical device after laser treatment, according to an embodiment of this invention.

FIG. 10 illustrates a schematic cross-sectional view of an opening in the interposer or electrical device substantially filled with high conductivity paste, according to an embodiment of this invention.

FIG. 11 illustrates a flow diagram of the fabrication of the interposer, according to an embodiment of this invention.

FIG. 12 illustrates a cross-sectional view of a laminated and sintered ceramic interposer or electrical device, undergoing laser ablation according to an embodiment of this invention.

FIG. 13 illustrates a schematic side view of an opening being formed in the interposer or electrical device by laser ablation, according to an embodiment of this invention.

FIG. 14 illustrates a flow diagram of the fabrication of an interposer or electrical device, according to an embodiment of this invention.

FIG. 15 is a cross-sectional schematic diagram of laser forming an electrical trace on the surface of a ceramic device, according to another embodiment of this invention.

The description set out herein illustrates some embodiments of the invention, and such description is not intended to be construed as limiting in any manner.

### DETAILED DESCRIPTION

In the following detailed description of the preferred embodiments, reference is made to the accompanying drawings that form a part hereof, and in which are shown by way of illustration specific embodiments in which the invention can be practiced. The embodiments illustrated are described in sufficient detail to enable those skilled in the art to practice the teachings disclosed herein. Other embodiments can be utilized and derived therefrom, such that structural and logical substitutions and changes can be made without departing from the scope of present inventions. The following detailed description, therefore, is not to be taken in a limiting sense, and the scope of various embodiments of the invention is defined only by the appended claims, along with the full range of equivalents to which such claims are entitled.

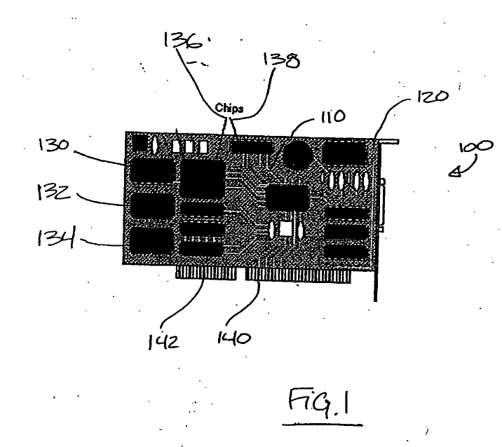

FIG. 1 is a top view of a printed circuit board 100 having a component with an interposer, according to an embodiment of the invention. The printed circuit board (“PCB”) 100 is a multi-layer plastic board that includes patterns of printed circuits on one or more layers of insulated material. The patterns of conductors correspond to wiring of an electronic circuit formed on one or more of the layers of the printed circuit board 100. The printed circuit board 100 also includes electrical traces 110. The electrical traces 110 can be found on an exterior surface 120 of the printed circuit board 100, and also can be found on the various layers within the printed circuit board 100. Printed circuit boards also include through holes (not shown in FIG. 1), which are used to interconnect traces on various layers of the printed circuit board 100. The printed circuit board 100 can also include planes of metallized materials such as ground planes, power planes, or voltage reference planes (not shown in FIG. 1).

The printed circuit board 100 is also populated with various components 130, 132, 134, 136, 138. The components 130, 132, 134, 136, 138 can either be discrete components or semiconductor chips which include thousands of transistors. The components 130, 132, 134, 136, 138 can use any number of technologies to connect to the exterior surface 120 of the printed circuit board 100. For example, pins may be inserted into plated through holes, or pins may be extended through the printed circuit board 100. An alternative technology is surface mount technology, where an electrical component, such as component 136, mounts to an array of pads on the exterior surface 120 of the printed circuit board 100. For example, component 136 could be a ball grid array package or device, that has an array of balls or bumps that interact or are connected to a corresponding array of pads on the exterior surface 120 of the printed circuit board 100. The printed circuit board 100 can also include connectors for making external connections to other electrical or electronic devices. The component 136 could be a processing chip or microprocessor.

As shown in FIG. 1, the printed circuit board 100 includes a first edge connector 140 and a second edge connector 142. As shown in FIG. 1 there are external traces, such as electrical trace 110, on the external surface 120 of the printed circuit board 100, that connect to certain of the outputs associated with the first edge connector 140. Other traces that connect with the edge connectors 140, 142 will have traces internal to the printed circuit board 100.

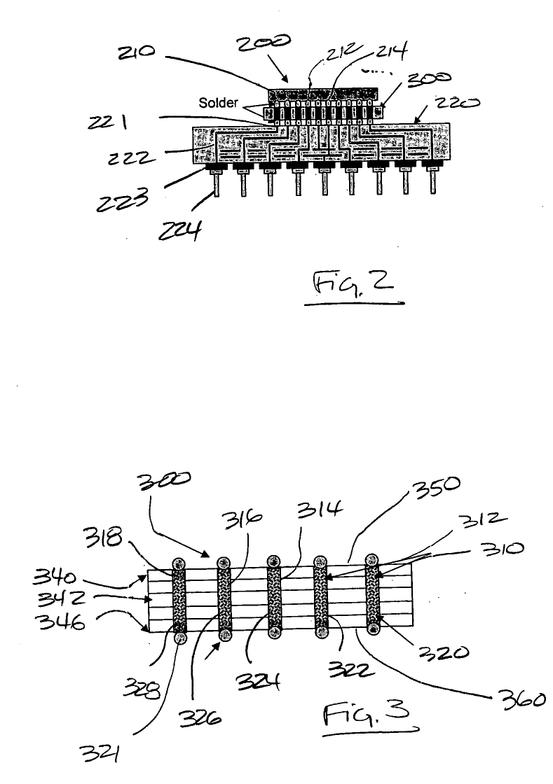

FIG. 2 illustrates a schematic cross-sectional view of a package 200 having a die 210, an interposer 300 and a substrate 220, according to an embodiment of this invention. The die 210 includes electrical circuitry of various types. One common use for a die 210 is for the circuitry of a microprocessor. The die 210 actually includes layers upon layers of electrical devices, such as transistors and other logic devices. The die 210 includes a number of electrical outputs, such as output 212 and electrical inputs, such as electrical input 214. As shown in FIG. 2, the electrical outputs and the electrical inputs, such as 212, 214, are in a ball grid array. A ball grid array includes an array of solder balls formed on one of the major surfaces of the die 210. The ball grid array, which includes an output 212 and an input 214, is also known as a flip chip that includes a number of bumps for the various inputs and outputs of the circuitry within the die 210. The bumps, such as output 212 and input 214, provide for a much more dense packing of inputs and outputs for the die 210.

The interposer 300 is connected between the die 210, and more specifically the inputs and outputs of the die 210, and the substrate 220. As shown in FIG. 3, the interposer 300 includes a plurality of through holes 310, 312, 314, 316 and 318. The plurality of through holes 310, 312, 314, 316, 318 are filled with high conductivity metallic paste, as depicted by reference numbers 320, 322, 324, 326, 328. The paste 320, 322, 324, 326, 328 has substantially no adhesion-promoting fillers, since the through openings 310, 312, 314, 316, 318 include a metalized inner surface. The metalized inner surface of the through holes or vias 310, 312, 314, 316, 318 lessens or eliminates the need for an adhesion-promoting filler within the metallic paste in the vias or through openings. The interposer 300 also includes a number of sheets or layers 340, 342, 346. Although FIG. 3, shows five layers or sheets, only three of the layers carry reference numerals. Any number of layers can be used to form the interposer 300. The interposer 300 is typically formed of a material that has a coefficient of thermal expansion with a value that is between the value of the coefficient of thermal expansion of the die 210 and the value of the coefficient of thermal expansion of the substrate 220 (see FIG. 2). In some embodiments of the interposer 300, the individual layers may include electrical or conductive traces or pathways. In addition, the exterior major surfaces 350 and 360 of the interposer 300 may include electrical traces which fan out, further separate, or lessen the density of the bumps of the ball grid array associated with the die 210.

Now returning to FIG. 2, the substrate 220 also includes solder balls or contact points for solder balls on a surface for connecting the interposer 300 to a corresponding pad 223 on an opposite major surface. An electrical trace 222 connects the contact point 221 and the pad 223 of the substrate 220. A pin or other output or input device 224 may be in electrical communication with the pad 223. A solder ball, such as solder ball 321 (see FIG. 3), electrically connects the via 318 and the paste within the via 328 of the interposer 300 with the substrate 220 at an attachment point 221. As shown in FIG. 2, electrical traces, such as electrical trace 222 within the substrate 220, fan out so that each pin, such as pin 224, can be further spaced from an adjacent pin. The larger spacing between the pins, such as pin 224, also provides for a more substantial input or output pin which can be plugged into a connector associated with the printed circuit board 100. The output of the substrate 220 need not be a pin 224, as shown in FIG. 2. The output of the substrate 220 can be any other number of commonly used electrical outputs, such as solder bumps or the like.

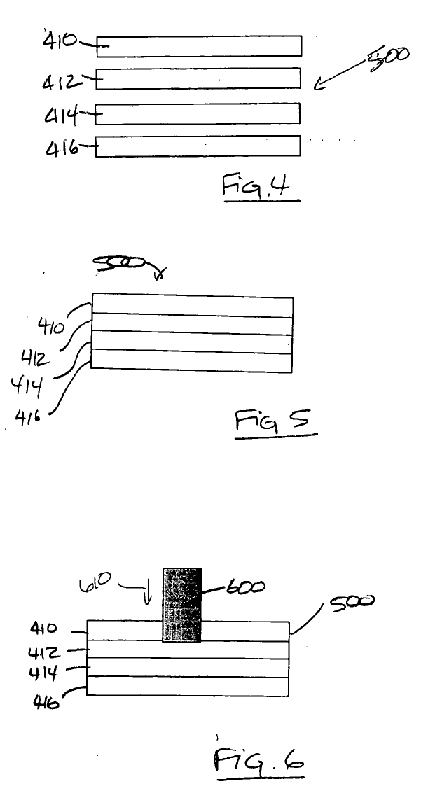

Now turning to FIGS. 4-10, the process for fabricating an electrical device such as the ceramic interposer 300 will now be discussed. FIG. 4 illustrates a schematic exploded view of a plurality of substantially ceramic layers that form an interposer 500, according to an embodiment of this invention. It should be noted that any number of layers can be used to form the electrical device, such as the interposer 500. As shown in FIG. 4, the electrical device includes a first layer 410, a second layer 412, a third layer 414, and a fourth layer 416. It should be noted that the electrical device, such as the interposer 500, can be varied in thickness by using either more or fewer layers. Each of the substantially ceramic layers is formed of or includes aluminum nitride. An amount of aluminum nitride (AlN) within the ceramic allows for laser direct metallization of the ceramic. In other words, by directing a laser at the surface or at the ceramic that includes aluminum nitride in an appropriate concentration intensity, a metal surface is formed. The layers 410, 412, 414, 416 can be formed from green, unfired sheets of ceramic, hereinafter referred to as sheets. The sheets 410, 412, 414, 416 come off of rolls of ceramic material, such as those used in a tape-casting process. In other words, the sheets 410, 412, 414, 416 are made of a material which, in the presence of a laser, converts the originally insulative ceramic (such as aluminum nitride AlN) into a conductor, such as a aluminum, by selective photo ablation. A material that converts from an originally insulative state into a conductive state in the presence of a laser of appropriate type, power and wavelength is referred to as a laser active conversion material. Other materials can be included in an appropriate concentration intensity so that in the presence of a laser, a metal surface is formed. Other such materials include silicon carbide (SiC) and silicon nitride (Si₃N₄) and similar materials placed within a ceramic. The green, unfired sheets 410, 412, 414, 416 are malleable.

FIG. 5 illustrates a schematic side view of an electrical device or interposer 500 in which the various layers 410, 412, 414, 416 have been laminated. The number of green, unfired sheets used 410, 412, 414, 416 produces a device or interposer 500 of a required or selected thickness. The number of sheets used can be varied to vary the thickness of the electrical device or interposer.

FIG. 6 illustrates a schematic side view of an interposer or electrical device with multiple laminated layers, as an opening is being formed in the device or interposer 500, according to an embodiment of this invention. As shown in FIG. 6, the electrical device having multiple layers 410, 412, 414, 416 is in the process of mechanical punching of the green, unfired sheets to form a through hole or via within the electrical device 500. A punch 600, as shown in FIG. 6, travels in a direction 610 relative to the electrical device or interposer 500. The punch 600 has progressed through layer 410 and slightly into layer 412 of the interposer 500.

FIG. 7 illustrates a schematic side view of an interposer or electrical device 500 having a through hole or via 720 formed therein. The through hole or via 720 extends through each of the layers 410, 412, 414, 416. After the through hole or via 720 is punched or formed by the mechanical punch 600 (see FIG. 6), the electrical device or interposer 500 with the through hole 720 is sintered. The sintering process heats the ceramic, laminated sheets 410, 412, 414, 416 to form a hard, ceramic device 500 having a through hole 720. Sintering of the punched ceramic device 500 essentially fires the ceramic. Forming the through hole or via 720 using the punch 600 on green sheets of ceramic 410, 412, 414, 416 (see FIG. 6) permits the vias or through holes 720 to be formed accurately and easily when compared to forming through holes in a ceramic device that has been fired.

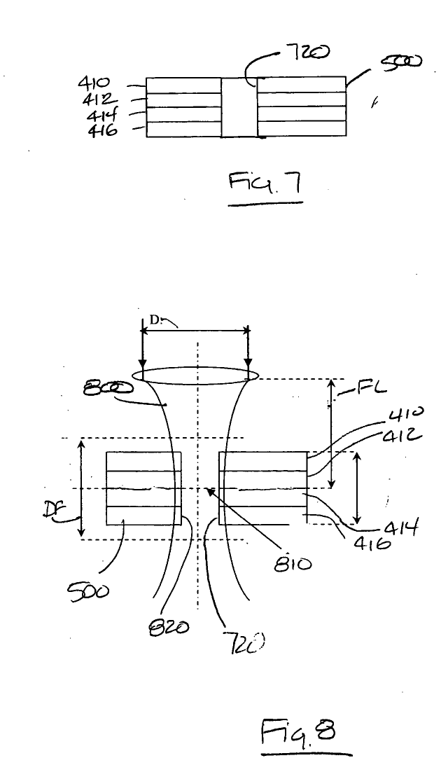

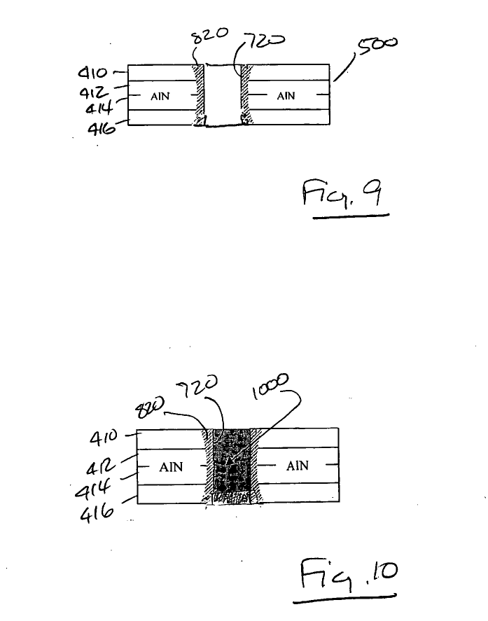

FIG. 8 illustrates a schematic view of an opening or via 720 within the electronic device or ceramic interposer 500 undergoing laser treatment, according to an embodiment of this invention. As shown in FIG. 8, a laser beam 800 having a diameter, D, and a focal length, FL, is applied to the via or opening 720 in the electrical device or interposer. The laser has a depth of focus, DF. The focal plane 810 occurs approximately midway along the length of the via or through opening and can be adjusted along any specific location according to the specific design of a given device 720. Laser interaction with the ceramic interposer or ceramic device 500 forms a laser direct metalized phase along the length of the through hole or via 720. In other words, a direct-metalized phase is formed on the walls 820 of the through hole or via 720. The laser is applied to the walls 820 of the through opening or via 720 with a sufficient intensity to form the metallic conductive phase along the through hole wall. The laser induced metallic phase is embedded at the surface of the laser-metalized ceramic and acts as an inner connect line or conductive trace along the walls or in the wall 820 of the via or through hole 720.

FIG. 9 illustrates a schematic cross sectional view of an opening 720 after the laser treatment or selective laser irradiation of the opening 720, according to an embodiment of this invention. As shown in FIG. 9, the walls 820 near the opening or through hole or via 720 are rich with aluminum. The aluminum-rich walls act as a conductor embedded within the walls 820 of the through opening or via 720.

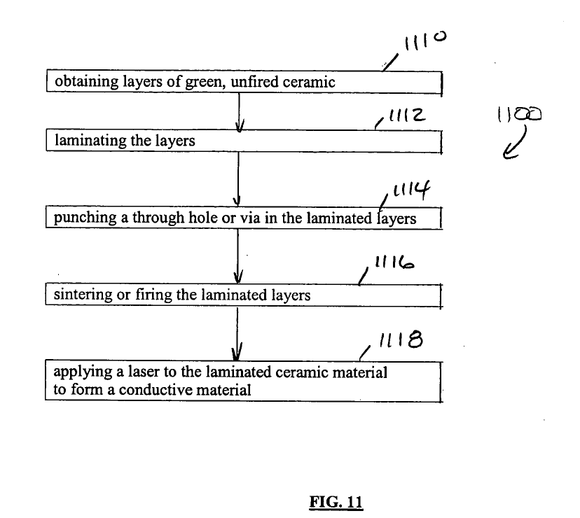

FIG. 10 is a schematic cross sectional view of an opening 720 substantially filled with a high conductivity paste 1000. The high conductivity paste 1000 is devoid or substantially devoid of adhesion-promoting filler. When adhesion-promoting fillers are used, the electrical properties of the paste plug 1000 are less desirable than the high-conductivity paste 1000 which is shown in FIG. 10. The adhesion properties between the conductive filler paste 1000 and the ceramic interposer or device 500 are enhanced by creating the metallic conductive phase along the wall 820 of the through hole or via 720. This either allows for elimination of an adhesive promoting agent or substantial reduction in an adhesive promoting agent in the conductive paste. As a result, the high conductivity paste has enhanced electrical conductivity properties, when compared to filler pastes that have adhesion-promoting fillers. The improved adhesion between the high conductivity filler paste, such as silver-based paste, and the laser-metalized wall 820 of the through opening 720, eliminates or reduces the need for filler particles in the providing conductive paste.

Additionally, the formation of the metalized phase in the wall 820 of the through opening 720 decouples the curing of the conductive paste step from the sintering step. It should be noted that in another embodiment of this invention, rather than using aluminum nitride within the ceramic, other ceramics can also be used. For example, silicon carbide (SiC) can also be used. The selective laser irradiation of the opening results in a metal or semi metal species of silicon in the walls 820 near the opening 720 of the ceramic electrical device 500. In still further embodiments, another material such as silicon nitride_(Si₃N₄) can also be used to produce a metalized or semi metalized species of material in the walls 820 near the opening or through hole or via 720 in the electrical device or interposer 500.

FIG. 11 illustrates a flow diagram of a method 1100 for fabrication of an electrical device, such as an interposer, according to an embodiment of this invention. The method 1100 for forming an electrical device includes obtaining layers of green, unfired ceramic 1110, laminating the layers 1112, punching a through hole or via in the laminated layers 1114, sintering or firing the laminated layers 1116, and applying a laser to the laminated ceramic material to form a conductive material 1118. In one embodiment, applying a laser to the ceramic material 1118 to form conductive material includes directing a laser toward a surface of the ceramic material. In another embodiment, applying a laser to the ceramic material 1118 to form conductive material includes directing a laser toward a via within the ceramic material. In yet another embodiment of the method 1100, applying a laser to the ceramic material 1118 to form conductive material includes directing a laser toward a surface of the ceramic material, and moving one of the laser and the ceramic material to form a conductive path on the surface of the ceramic material. Applying the laser 1118 also includes directing a laser toward a surface of the ceramic material, and directing a laser toward a via within the ceramic material. In some embodiments, the method 1110 further includes moving one of the laser and the ceramic material to form a conductive path on the surface of the ceramic material. The shape and the dimensions of the conductive phases formed in each of those different embodiments are well controlled and can be defined

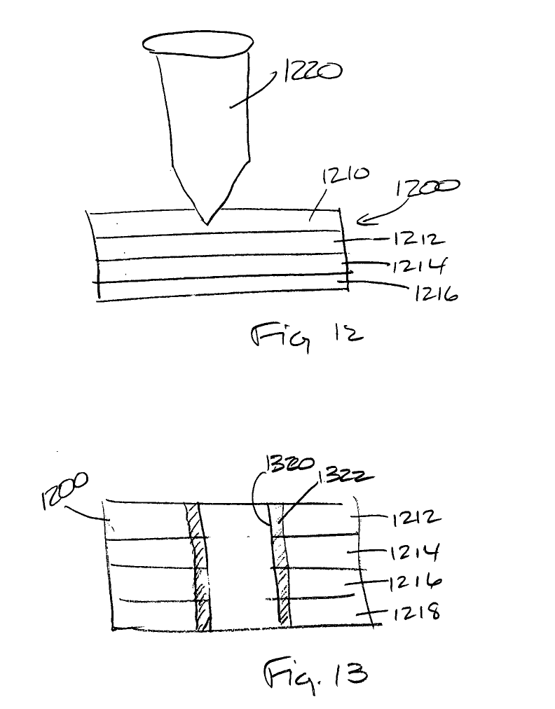

FIG. 12 illustrates a cross sectional view of a laminated and sintered ceramic electrical device or interposer 1200 undergoing laser ablation by a laser 1220. The laser 1220 is used to produce an opening, or laser ablate material of the ceramic interposer or electrical device. As the opening is formed, the laser focal point is moved further down into the layers of the ceramic electrical device or interposer 1200. As shown in FIG. 12, the laser 1220 is being directed into a layer 1210 of the ceramic interposer electrical device 1200. The ceramic interposer or device also includes a layer 1212, a layer 1214, and a layer 1216. As laser ablation occurs, an opening is formed.

FIG. 13 illustrates a schematic side view of an opening 1320 formed by laser ablation, according to an embodiment of this invention. The opening 1320 extends through layers 1212, 1214, 1216, 1218 of the ceramic electrical device or interposer 1200. A metal metallic or (conductive) phase 1322 is formed in the walls near the opening 1320. Forming an opening by laser ablation also forms an opening having a metal (conductive) phase or semi-metallic phase in the walls near the opening, as depicted by reference numeral 1322. It should be noted that the layers 1212, 1214, 1216, 1218 are all formed of laser convertible material, such as AlN, SiC, or Si₃N₄. The opening 1320 can then be filled with a high conductivity metallic paste such as paste 1000, shown in FIG. 10.

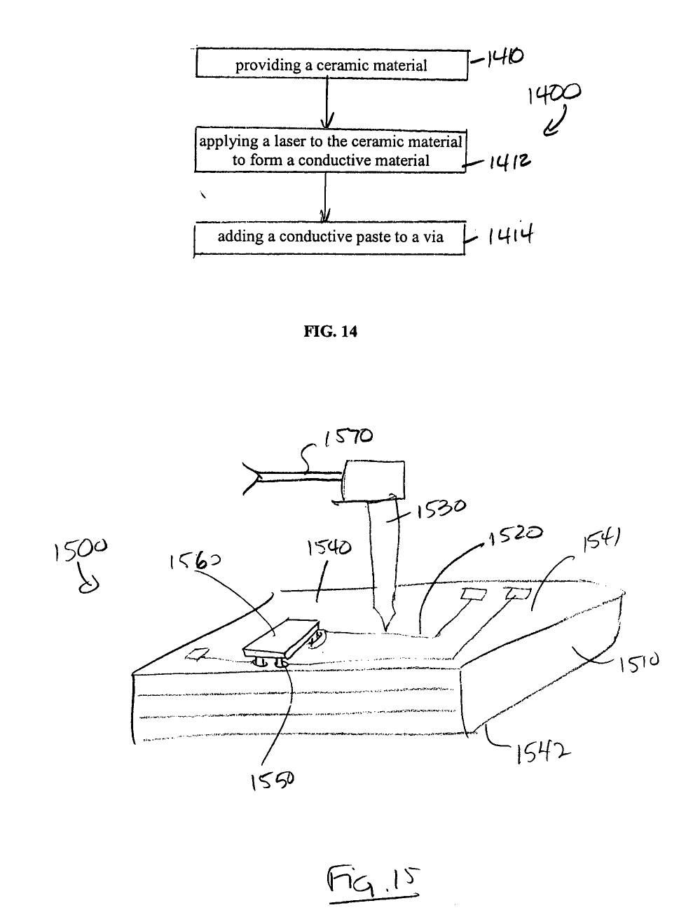

FIG. 14 illustrates a flow diagram of the fabrication of an electrical device such as an interposer, according to an embodiment of this invention. A method 1400 for forming an electrical device includes providing a ceramic material 1410, and applying a laser to the ceramic material to form a conductive material 1412. The ceramic material is a laser-conversion active ceramic material. In one embodiment, applying a laser to the ceramic material to form conductive material 1412 includes directing a laser toward a surface of the ceramic material. In another embodiment, applying a laser to the ceramic material to form conductive material 1412 includes directing a laser toward a via within the ceramic material. A conductive paste can be added to the via 1414. Adding a conductive paste to the via 1414 includes lowering the concentration of adhesion-promoting materials when compared to a conductive paste formulated to adhere to a nonmetallic surface on a via. In some embodiments, applying a laser to the ceramic material to form conductive material 1412 includes directing a laser toward a surface of the ceramic material, and moving one of the laser and the ceramic material to form a conductive path on the surface of the ceramic material. In some embodiments, providing the ceramic material further includes punching out a via from the ceramic material, and firing the ceramic material.

FIG. 15 is a cross-sectional schematic diagram of laser forming an electrical a conductive trace trace on the surface of a ceramic device, according to another embodiment of this invention. An apparatus 1500 includes a substrate 1510 of ceramic material, and a conductive path 1520 associated with the substrate 1510 formed by a laser 1530 directed at the ceramic material. The conductive path 1520 is on a surface 1540 of the substrate. The conductive path can also be associated with a via 1550 in the substrate. The substrate 1510 includes a first major surface 1541, a second major surface 1542, and a via 1550 positioned between the first major surface 1541 and the second major surface 1542. The substrate 1510 is formed from a laser-conversion active ceramic material. At least one of the first major surface 1541 and the second major surface 1542 includes a conductive path 1520 formed by a laser. The via 1550 includes a conductive portion formed by a laser. In some embodiments, at least one of the first major surface 1541 and the second major surface 1542 includes a conductive path 1520, and the via 1550 also includes a conductive portion. Both the conductive path 1520 and the conductive portion of the via 1550 are formed by the laser irradiation 1530. The laser irradiation 1530 is directed at the at least one of the first major surface 1541 and the second major surface 1542, and at a surface of the via 1550. The substrate 1510, in some embodiments, also includes an electrical device 1560 electrically attached to at least one of the conductive portion of the via 1550 or the conductive path 1520 of the substrate 1510. It should be noted that although the laser 1530 and the other electrical device 1560 are shown together, most generally the laser 1530 would be used to form traces before the electrical device 1560 is attached to the substrate. It is also worth to mention that due to the non contact nature of the laser metallization process, laser irradiation can be used after device attachement to the substrate for some additional purposes, such as repair or trimming of a conductive trace or similar operations.

The apparatus 1500 includes a substrate 1510 including a laser-conversion active ceramic material, and a device for directing a laser 1530 toward the substrate 1510 to form a conductive material associated with the substrate 1510. The device for directing a laser toward the substrate 1510, in some embodiments, further includes a device for moving one of a laser or the substrate l 150 to produce relative motion between the laser and the substrate. In other embodiments, the device for directing a laser toward the substrate further includes a device for directing a laser at the substrate to form a via. Different type of lasers can be used in embodiments of the invention depending upon: the type of material, the level of conductivity needed and the dimensions of the traces required. In an embodiment, ultraviolet lasers (UV-lasers) with short wavelength (<350 nm) and short pulse width (100-20 nano second) can be used. In this range of wavelength the laser type can either be solid state laser (such as third harmonic or forth harmonic Nd:YAG laser) or it can be gas laser such as the Excimer laser with different wavelength and lasing mediums. With respect to the thickness of materials of the via diameter there is a limit to the size when the substrate is formed and fired and the laser is used to form a via in the fired ceramic substrate. The limit of the diameter of the via will be in the range of 20 microns to 50 microns. The limit is dependent on the wavelength of the laser used as well as the power needed to produce a via in a desired amount of time.

In some embodiments, a laser is directed at the ceramic material to form a via. In other embodiments, an opening is punched in the ceramic substrate, and the ceramic substrate is fired.

The foregoing description of the specific embodiments reveals the general nature of the invention sufficiently that others can, by applying current knowledge, readily modify and/or adapt it for various applications without departing from the generic concept, and therefore such adaptations and modifications are intended to be comprehended within the meaning and range of equivalents of the disclosed embodiments.

It is to be understood that the phraseology or terminology employed herein is for the purpose of description and not of limitation. Accordingly, the invention is intended to embrace all such alternatives, modifications, equivalents and variations as fall within the spirit and broad scope of the appended claims.

What is claimed is:

1. A method for forming an electrical device comprising:
providing a ceramic material; and
applying a laser to the ceramic material to form a conductive material.

2. The method of claim 1 wherein applying a laser to the ceramic material to form conductive material includes directing a laser toward a surface of the ceramic material.

3. The method of claim 1 wherein applying a laser to the ceramic material to form conductive material includes directing a laser toward a via within the ceramic material.

4. The method of claim 1 wherein applying a laser to the ceramic material to form conductive material includes:
directing a laser toward a surface of the ceramic material; and
moving one of the laser and the ceramic material to form a conductive path on the surface of the ceramic material.

5. The method of claim 1 wherein the ceramic material is a laser-conversion active ceramic material.

6. The method of claim 3 further comprising adding a conductive paste to the via.

7. The method of claim 6 wherein adding a conductive paste includes selecting a paste substantially devoid of adhesion-promoting materials to adhere to a nonmetallic surface on a via.

8. The method of claim 1 wherein providing the ceramic material further includes:
punching out a via from the ceramic material; and
firing the ceramic material.

9. The method of claim 1 wherein applying a laser to the ceramic material to form conductive material includes directing a laser toward a through hole within the ceramic material.

10. A substrate comprising:
a first major surface;
a second major surface; and
a via positioned between the first major surface and the second major surface, the substrate formed from a laser-conversion active ceramic material.

11. The substrate of claim 10 wherein at least one of the first major surface and the second major surface includes a conductive path formed by a laser.

12. The substrate of claim 10 wherein the via includes a conductive portion formed by a laser.

13. The substrate of claim 10 wherein at least one of the first major surface and the second major surface includes a conductive path and wherein the via includes a conductive portion, wherein the conductive path and the conductive portion are formed by a laser.

14. The substrate of claim 10 wherein at least one of the first major surface and the second major surface includes a conductive path and wherein the via includes a conductive portion, wherein the conductive path and the conductive portion are formed by a laser directed at the at least one of the first major surface and the second major surface and at a surface of the via.

15. The substrate of claim 13 further comprising an electrical device electrically attached to at least one of the conductive portion and the conductive path of the substrate.

16. A method for forming an electrical device comprising:
providing a ceramic material; and
applying a laser to the ceramic material to form a conductive material.

17. The method of claim 16 wherein applying a laser to the ceramic material to form conductive material includes directing a laser toward a surface of the ceramic material.

18. The method of claim 16 wherein applying a laser to the ceramic material to form conductive material includes directing a laser toward a via within the ceramic material.

19. The method of claim 16 wherein applying a laser to the ceramic material to form conductive material includes:
directing a laser toward a surface of the ceramic material; and
directing a laser toward a via within the ceramic material.

20. The method of claim 19 further comprises moving one of the laser and the ceramic material to form a conductive path on the surface of the ceramic material.

21. The method of claim 16 further comprising directing a laser toward the substrate to form a via in the substrate.

22. The method of claim 16 further comprising directing a laser toward another surface of the ceramic material.

23. The method of claim 16 further comprising directing a laser at the ceramic material to form a via.

24. The method of claim 16 further comprising:
punching an opening in the ceramic substrate; and
firing the ceramic substrate.

25. An apparatus comprising
a substrate of ceramic material; and
a conductive path associated with the substrate formed by a laser directed at the ceramic material.

26. The apparatus of claim 25 wherein the conductive path is on a surface of the substrate.

27. The apparatus of claim 25 wherein the conductive path is associated with a via in the substrate.

28. An apparatus comprising:
a substrate including a laser-conversion active ceramic material; and
means for directing a laser toward the substrate to form a conductive material associated with the substrate.

29. The apparatus of claim 28 wherein means for directing a laser toward the substrate further includes means for moving at least one of a laser or the substrate to produce relative motion between the laser and the substrate.

30. The apparatus of claim 28 wherein means for directing a laser toward the substrate further includes means for directing a laser at the substrate to form a via.
